(19) United States
(12) Patent Application Publication
(10) Pub. No.: US 2017/0207326 A1
(43) Pub. Date: Jul. 20, 2017

(54) METHOD OF MANUFACTURING THIN-FILM TRANSISTOR SUBSTRATE

(71) Applicant: JOLED INC., Tokyo (JP)

(72) Inventor: Tohru SAITOH, Tokyo (JP)

(21) Appl. No.: 15/314,942

(22) PCT Filed: Jun. 2, 2015
(86) PCT No.: PCT/JP2015/002777

§ 371 Date: Nov. 30, 2016

(30) Foreign Application Priority Data
Jun. 3, 2014 (JP) 2014-115264

(51) Int. Cl. H01L 29/66; H01L 27/32; H01L 21/283; H01L 29/786; H01L 21/02

(52) U.S. Cl. CPC H01L 29/66969; H01L 29/7869; H01L 21/02164; H01L 21/283; H01L 27/3246; H01L 27/3276; H01L 2227/323

(57) ABSTRACT

A method of manufacturing a TFT substrate that includes a thin-film transistor having an oxide semiconductor layer includes forming a source line above a substrate 2, the source line being a copper line including a stacked film of a copper film and a cap film on the copper film, depositing an insulating layer on the source line, and performing heat treatment at a temperature over 290° C. after the deposition of the insulating layer. The depositing of the insulating layer includes depositing a first silicon oxide film at 290° C. or lower, and depositing a second silicon oxide film above the first silicon oxide film at 290° C. or lower. A total film thickness of the first silicon oxide film and the second silicon oxide film is 460 nm or more.

### CROSS-REFERENCE TO RELATED APPLICATION

The present application is a National Phase of International Application Number PCT/JP2015/002777, filed Jun. 2, 2015, which claims priority to Japanese Application Number 2014-115264, filed Jun. 3, 2014.

### TECHNICAL FIELD

The present disclosure relates to a method of manufacturing a thin-film transistor substrate.

### BACKGROUND ART

Active matrix display devices such as liquid crystal display devices and organic EL display devices use thin-film transistor (TFT) substrates that include TFTs serving as switching elements or driving elements.

TFTs using oxide semiconductors have been developed in recent years. For example, Patent Literature (PTL) 1 discloses an oxide semiconductor TFT that uses an oxide semiconductor as a channel layer.

### CITATION LIST

### Patent Literature

[PTL 1]

Japanese Unexamined Patent Application Publication No. 2010-161227

### SUMMARY OF DISCLOSURE

### Technical Problem

It is, however, difficult for the TFT substrates including oxide semiconductor TFTs to achieve desired performance.

The technique disclosed herein aims to provide a method of manufacturing a TFT substrate, with which it is possible to obtain a TFT substrate with desired performance.

### Solution to Problem

In order to achieve the object described above, the method of manufacturing a TFT substrate according to an embodiment is a method of manufacturing a thin-film transistor substrate that includes a thin-film transistor having an oxide semiconductor layer. The method includes forming a copper line above a substrate, the copper line including a stacked film that includes a copper film and a cap film on the copper film, depositing an insulating layer on the copper line, and performing heat treatment at a temperature over 290° C. after the deposition of the insulating layer. The depositing of the insulating layer includes depositing a first silicon oxide film at a film deposition temperature of 290° C. or lower, and depositing a second silicon oxide film above the first silicon oxide film at a film deposition temperature of 290° C. or lower. A total film thickness of the first silicon oxide film and the second silicon oxide film is greater than or equal to 460 nm.

### Advantageous Effects of Disclosure

With this method, a TFT substrate with desired performance can be achieved.

### BRIEF DESCRIPTION OF DRAWINGS

FIG. 1 is a cutaway perspective view of part of an organic EL display device according to an embodiment.

FIG. 2 is a perspective view illustrating an example of pixel banks of the organic EL display device according to the embodiment.

FIG. 3 is an electric circuit diagram illustrating a structure of a pixel circuit in the organic EL display device according to the embodiment.

FIG. 4 is a schematic diagram illustrating the layout of a pixel in a TFT substrate according to the embodiment.

FIG. 5 is a cross-sectional view of the TFT substrate of the embodiment, taken along line A-A′ in FIG. 4.

FIG. 6 is a schematic cross-sectional view of a TFT substrate according to Variation 1.

FIG. 7 is a schematic cross-sectional view of a TFT substrate according to Variation 2.

FIG. 8A is a cross-sectional view illustrating a step of forming a gate electrode in the method of manufacturing a TFT substrate according to the embodiment.

FIG. 8B is a cross-sectional view illustrating a step of forming a first insulating layer (gate insulating film) in the method of manufacturing a TFT substrate according to the embodiment.

FIG. 8C is a cross-sectional view illustrating a step of forming an oxide semiconductor layer in the method of manufacturing a TFT substrate according to the embodiment.

FIG. 8D is a cross-sectional view illustrating a step of forming a second insulating layer in the method of manufacturing a TFT substrate according to the embodiment.

FIG. 8E is a cross-sectional view illustrating a step of forming contact holes in the insulating layer in the method of manufacturing a TFT substrate according to the embodiment.

FIG. 8F is a cross-sectional view illustrating a step of forming a metal stacked film in the method of manufacturing a TFT substrate according to the embodiment.

FIG. 8G is a cross-sectional view illustrating a step of patterning the metal stacked film (step of forming a source electrode, a drain electrode, and a source line) in the method of manufacturing a TFT substrate according to the embodiment.

FIG. 8H is a cross-sectional view illustrating a step of manufacturing a third insulating layer in the method of manufacturing a TFT substrate according to the embodiment.

FIG. 8I is a cross-sectional view illustrating a heat treatment step in the method of manufacturing a TFT substrate according to the embodiment.

FIG. 9A illustrates an in-plane scanning electron microscope (SEM) image showing abnormal growth of Cu from a Cu film of a source line at the intersection of a gate line and the source line.

FIG. 9B illustrates a cross-sectional SEM image taken along line B-B′ in FIG. 9A.

FIG. 10A schematically illustrates abnormal growth of Cu from the Cu film of a source line at the intersection of a gate line and the source line.

FIG. 10B is a cross-sectional view taken along line C-C′ in FIG. 10A.

FIG. 11 illustrates conditions for film deposition and heat treatment of the insulating layers and experimental results indicating the presence or absence of abnormal Cu growth.

FIG. 12 schematically illustrates the film structure of the source line and the insulating layer under each condition in FIG. 11.

FIG. 13 illustrates an in-plane SEM image at the intersection of a gate line and a source line under the condition that no abnormal Cu growth has occurred.

FIG. 14A illustrates a relationship between the electric field strength and the current density in a metal-oxide-metal structure obtained by depositing a second silicon oxide film at a film deposition temperature of 230° C.

FIG. 14B illustrates a relationship between the electric field strength and the current density in a metal-oxide-metal structure obtained by depositing the second silicon oxide film at a film deposition temperature of 290° C.

### DESCRIPTION OF EMBODIMENTS

Hereinafter, an embodiment of the present disclosure will be described with reference to the drawings. It is to be noted that the embodiment described below is a non-limiting specific example in the present disclosure. Thus, for example, numerical values, shapes, materials, constituent elements, the arrangement and connection of constituent elements, steps, and the order of steps given in the following embodiment are mere examples and do not intend to limit the scope of the present disclosure. Therefore, among the constituent elements in the following embodiment, constituent elements that are not recited in any one of the independent claims which define the generic concept of the present disclosure are described as arbitrary constituent elements.

Note that the drawings are schematic diagrams and do not always strictly follow the actual configuration. In the drawings, constituent elements that are substantially the same are given the same reference numerals, and a redundant description thereof is either omitted or simplified.

Embodiment

First, a configuration of an organic EL display device will be described as an example of a display device using a TFT substrate.

Organic EL Display Device

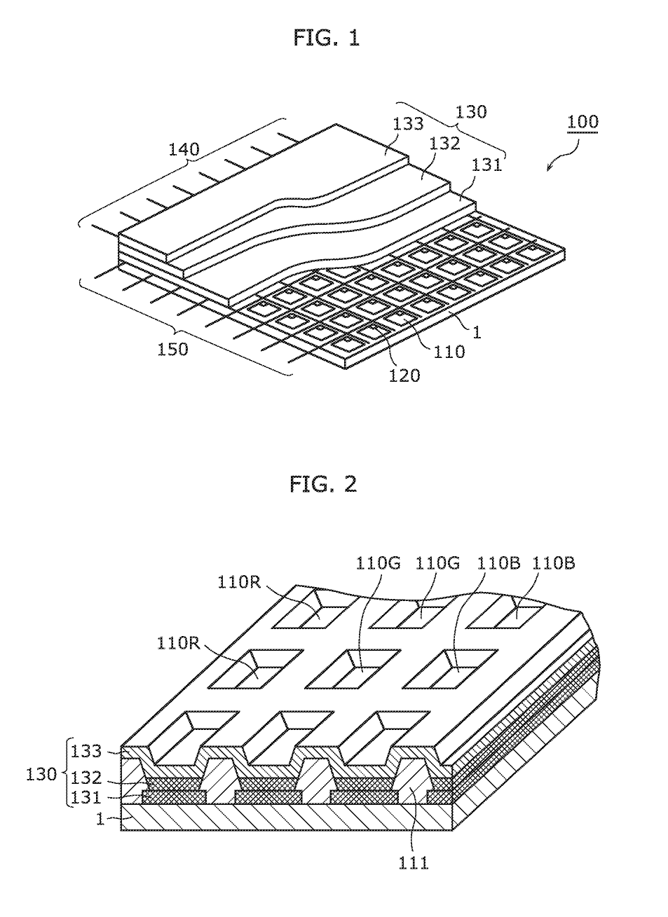

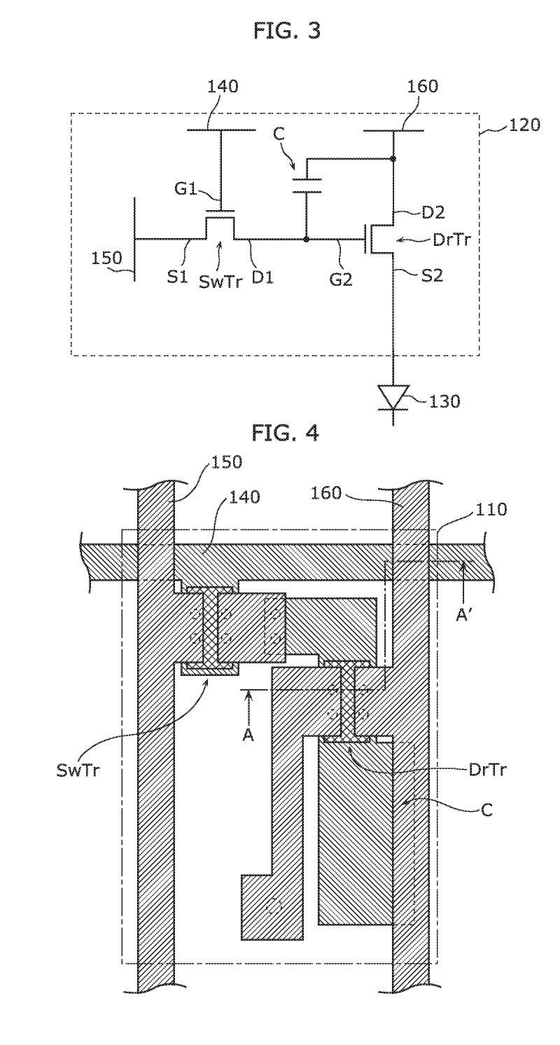

FIG. 1 is a cutaway perspective view of part of an organic EL display device according to an embodiment. FIG. 2 is a perspective view illustrating an example of pixel banks of the organic EL display device according to the embodiment.

As illustrated in FIG. 1, the organic EL display device 100 has a stacked structure configured by a TFT substrate (TFT array substrate) 1 on which a plurality of thin-film transistors are arranged, and organic EL elements (light emitting parts) 130 that include an anode 131 serving as a lower electrode, an EL layer 132 serving as a light emitting layer made of an organic material, and a cathode 133 serving as a transparent upper electrode.

The organic EL display device 100 according to the present embodiment is of a top-emission type, and the anode 131 is a reflecting electrode. The organic EL display device 100 is, however, not limited to a top-emission type organic EL display device and may be a bottom-emission type organic EL display device.

The TFT substrate 1 has a plurality of pixels 110 arranged in a matrix, each pixel 110 including a pixel circuit 120.

The organic EL elements 130 correspond respectively to the plurality of pixels 110, and the pixel circuit 120 of each pixel 110 controls light emission of each organic EL element 130. The organic EL elements 130 are formed on an interlayer insulation film (planarizing layer) that is formed to cover the plurality of thin-film transistors.

The organic EL elements 130 are configured such that the EL layer 132 is arranged between the anode 131 and the cathode 133. A hole transfer layer is further stacked between the anode 131 and the EL layer 132, and an electron transfer layer is further stacked between the EL layer 132 and the cathode 133. Note that other organic functional layers may be provided between the anode 131 and the cathode 133.

Each pixel 110 is driven and controlled by the corresponding pixel circuit 120. The TFT substrate 1 also includes a plurality of gate lines (scanning lines) 140 arranged in a row direction of the pixels 110, a plurality of source lines (signal lines) 150 arranged in a column direction of the pixels 110 to intersect with the gate lines 140, and a plurality of power lines (not shown in FIG. 1) arranged in parallel with the source lines 150. Each pixel 110 is partitioned by, for example, gate lines 140 and source lines 150 that are orthogonal to each other.

The gate lines 140 are connected respectively to the rows of gate electrodes of thin-film transistors that are included in each pixel circuit 120 and operate as switching elements. The source lines 150 are connected respectively to the columns of source electrodes of the thin-film transistors that are included in each pixel circuit 120 and operate as switching elements. The power lines are connected respectively to the columns of drain electrodes of thin-film transistors that are included in each pixel circuit 120 and operate as driving elements.

As illustrated in FIG. 2, each pixel 110 of the organic EL display device 100 consists of three color (red, green, and blue) sub-pixels 110R, 110G, and 110B, and these sub-pixels 110R, 110G, and 110B are arranged in a plurality of matrices on the display surface. Each of the sub-pixels 110R, 110G, and 110B is separated from the others by banks 111. The banks 111 are formed in a lattice such that projections extending in parallel with the gate lines 140 intersect with projections extending in parallel with the source lines 150. Portions surrounded by these projections (i.e., openings of the banks 111) are in one-to-one correspondence with the sub-pixels 110R, 110G, and 110B. While the banks 111 in the embodiment are pixel banks, the banks 111 may be line banks.

The anode 131 is formed on the interlayer insulator film (planarizing layer) of the TFT substrate 1 and within openings of the banks 111 for each of the sub-pixels 110R, 110G, and 110B. Similarly, the EL layer 132 is formed on the anode 131 and within the openings of the banks 111 for each of the sub-pixel 110R, 110G, and 110B. The transparent cathode 133 is continuously formed on the plurality of banks 111 to cover all of the EL layers 132 (all of the sub-pixels 110R, 110G, and 110B).

The pixel circuit 120 is provided for each of the sub-pixels 110R, 110G, and 110B, and each of the sub-pixels 110R, 110G, and 110B and the corresponding pixel circuit 120 are electrically connected to each other via contact holes and a relay electrode. Note that the sub-pixels 110R, 110G, and 110B have identical structures, except that the EL layers 132 emit different colors of light.

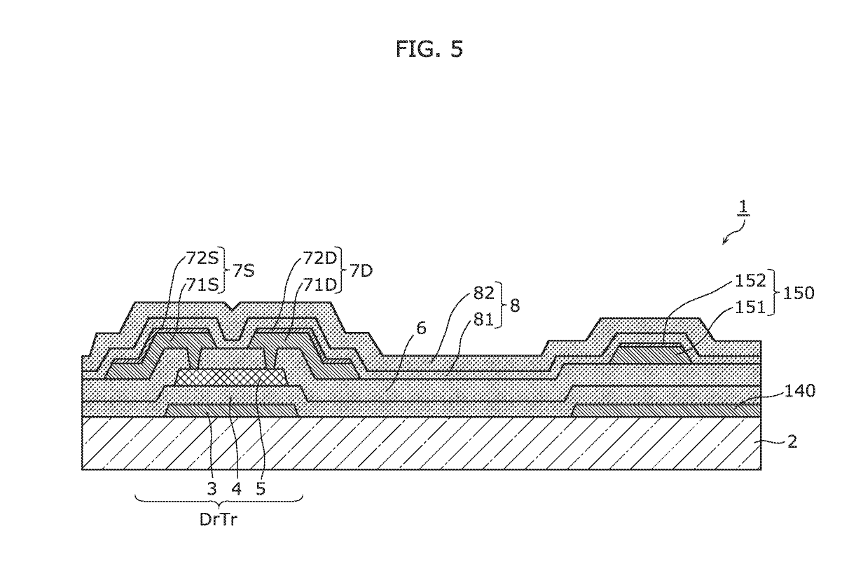

A circuit configuration of the pixel circuit 120 of each pixel 110 will now be described with reference to FIG. 3. FIG. 3 is an electric circuit diagram illustrating the configuration of a pixel circuit in the organic EL display device according to the embodiment.

As illustrated in FIG. 3, the pixel circuit 120 includes a thin-film transistor SwTr that operates as a switching element, a thin-film transistor DrTr that operates as a driving element, and a capacitor C that stores data for display on the corresponding pixel 110. In the present embodiment, the thin-film transistor Swtr is a switching transistor for selecting the pixel 30, and the thin-film transistor DrTr is a driving transistor for driving the organic EL element 130.

The thin-film transistor SwTr includes a gate electrode G1 that is connected to a gate line 140, a source electrode S1 that is connected to a source line 150, a drain electrode D1 that is connected to the capacitor C and a gate electrode G2 of the thin-film transistor DrTr, and a semiconductor film (not shown). In the thin-film transistor SwTr, when a predetermined voltage is applied to the connected gate line 140 and the connected source line 150, the voltage applied to the source line 150 is stored as a data voltage in the capacitor C.

The thin-film transistor DrTr includes the gate electrode G2 that is connected to the drain electrode D1 of the thin-film transistor SwTr and the capacitor C, a drain electrode D2 that is connected to a power line 160 and the capacitor C, a source electrode S2 that is connected to the anode 131 of the organic EL element 130, and a semiconductor film (not shown). The thin-film transistor DrTr supplies a current that corresponds to the data voltage stored in the capacitor C from the power line 160 via the source electrode S2 to the anode 131 of the organic EL element 130. As a result, a driving current flows from the anode 131 to the cathode 133, and the EL layer 132 emits light in the organic EL element 130.

The organic EL display device 100 with the above configuration adopts an active matrix method in which display control is performed for each pixel 110 located at the intersection of a gate line 140 and a source line 150. Thus, the thin-film transistors SwTr and DrTr of each pixel 110 (sub-pixels 110R, 110G, and 110B) selectively causes the corresponding organic EL element 130 to emit light, and accordingly a desired image is displayed.

TFT Substrate

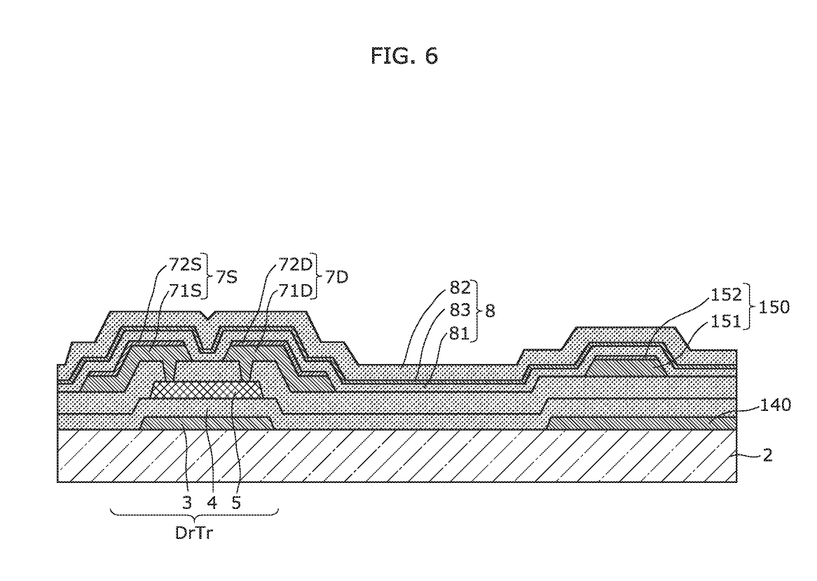

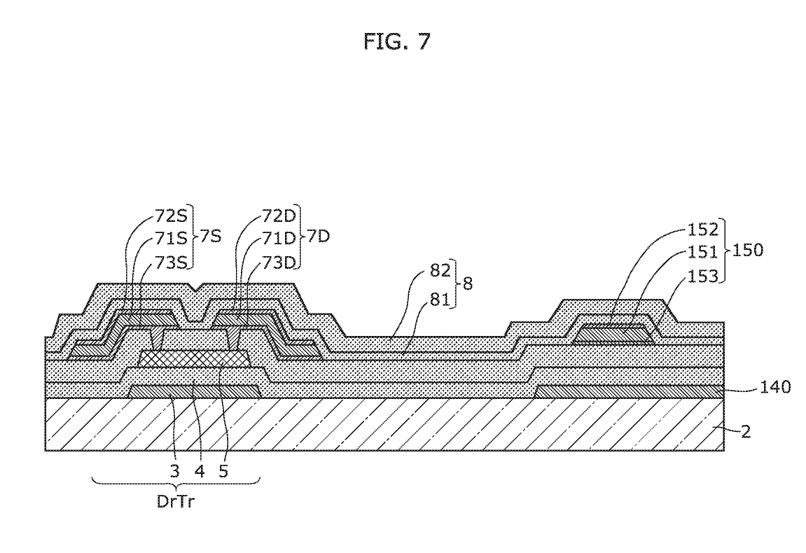

Next, a configuration of a TFT substrate according to the embodiment will be described with reference to FIGS. 4 and 5. FIG. 4 is a schematic diagram illustrating the layout of a pixel in a TFT substrate according to the embodiment. FIG. 5 is a cross-sectional view of the TFT substrate taken along line A-A′ in FIG. 4.

The following embodiment describes the TFT substrate 1 of the organic EL display device 100 described above.

As illustrated in FIG. 4, the pixels 110 (sub-pixels) are partitioned in a matrix by a plurality of gate lines 140 and a plurality of source lines 150 that are orthogonal to each other. As described above, each pixel 110 includes the thin-film transistor SwTr, the thin-film transistor DrTr, and the capacitor C.

As illustrated in FIG. 5, the TFT substrate 1 includes a substrate 2, a gate electrode 3, a gate insulating film 4, an oxide semiconductor layer 5, an insulating layer 6, a source electrode 7S, a drain electrode 7D, an insulating layer 8, the gate lines 140, and the source lines 150.

The gate electrode 3, the source electrode 7S, the drain electrode 7D, the gate lines 140, and the source lines 150 are made of a metal material, and layers where these electrodes and lines are formed are metal layers (interconnect layers). For example, the layer where the gate electrode 3 and the gate lines 140 are formed is a first interconnect layer (first metal layer), and the layer where the source electrode 7S, the drain electrode 7D, and the source lines 150 are formed is a second interconnect layer (second metal layer). Although not illustrated, the power lines 160 are also formed in the second interconnect layer. In each interconnect layer, lines and electrodes separated from one another in predetermined shapes may be formed by patterning a uniformly formed metal film (conductive film).

In the TFT substrate 1, the thin-film transistor DrTr is configured by the gate electrode 3, the gate insulating film 4, the oxide semiconductor layer 5, the source electrode 7S, and the drain electrode 7D as illustrated in FIG. 5. The gate electrode 3, the source electrode 7S, and the drain electrode 7D correspond respectively to the gate electrode G2, the source electrode S2, and the drain electrode D2 in FIG. 3.

The thin-film transistor Tr of the present embodiment is a bottom-gate type TFT and is also an oxide semiconductor TFT using an oxide semiconductor as a channel layer. The thin-film transistor SwTr may also have the same configuration as the thin-film transistor DrTr.

Hereinafter, components of the TFT substrate 1 will be described in detail with reference to FIG. 5.

The substrate 2 is, for example, a glass substrate such as a G8 substrate. Alternatively, the substrate 2 may be a flexible substrate such as a resin substrate. Note that an undercoat layer may be formed on the surface of the substrate 2.

The gate electrode 3 and the gate lines 140 are formed in predetermined shapes above the substrate 2. The gate electrode 3 and the gate lines 140 may be made of a metal such as titanium (Ti), molybdenum (Mo), tungsten (W), aluminum (Al), gold (Au), or copper (Cu), or a conductive oxide such as indium tin oxide (ITO). In the case of using a metal, an alloy such as molybdenum tungsten (MoW) may be used as a material for the gate electrode 3 and the gate lines 140.

The gate insulating film 4 is formed on the substrate 2 to cover the gate electrode 3 and the gate lines 140. The gate insulating film 4 is formed between the gate electrode 3 and the oxide semiconductor layer 5 and between the gate lines 140 and the source lines 150. The gate insulating film 4 is, for example, a single-layer film of thin oxide such as a silicon oxide film or a hafnium oxide film, of nitride such as a silicon nitride film, or of silicon oxynitride; or a stacked film of these films.

The oxide semiconductor layer 5 is formed in a predetermined shape above the substrate 2. The oxide semiconductor layer 5 is a channel layer (semiconductor layer) of the thin-film transistor DrTr and formed to face the gate electrode 3. For example, the oxide semiconductor layer 5 is formed in an island shape on the gate insulating film 4 above the gate electrode 3.

The oxide semiconductor layer 5 is preferably made of a transparent amorphous oxide semiconductor (TAOS) such as InGaZnOₓ (IGZO) containing indium (In), gallium (Ga), zinc (Zn), and oxide (O). The thin-film transistor using a transparent amorphous oxide semiconductor as its channel layer exhibits high carrier mobility and is suitable for large-screen, high-definition display device. The transparent amorphous oxide semiconductor can be deposited at low temperatures and thus can be easily formed on a flexible substrate.

For example, the InGaZnOₓ amorphous oxide semiconductor can be deposited by vapor deposition such as sputtering or laser deposition, using a polycrystalline sintered compact having a composition of InGaO₃ (ZnO)₄ as a target.

The insulating layer 6 is deposited on the gate insulating film 4 to cover the oxide semiconductor layer 5. That is, the oxide semiconductor layer 5 is covered with the insulating layer 6, and the insulating layer 6 functions as a protective layer (channel protective layer) that protects the oxide semiconductor layer 5. The insulating layer 6 is also deposited above the gate lines 140.

The insulating layer 6 is, for example, a single-layer oxide film such as a silicon oxide film (SiO₂) or an aluminum oxide film (Al₂O₃), or a stacked film of these oxide films. Part of the insulating layer 6 has openings that penetrate through the insulating layer 6, and the oxide semiconductor layer 5 is connected to the source electrode 7S and the drain electrode 7D through these openings (contact holes).

The source electrode 7S and the drain electrode 7D are formed in predetermined shapes on the insulating layer 6. More specifically, the source electrode 7S and the drain electrode 7D are connected to the oxide semiconductor layer 5 through the contact holes of the insulating layer 6, and spaced a predetermined distance from and face each other in a horizontal direction of the substrate on the insulating layer 6.

The source electrode 7S and the drain electrode 7D are both primarily made of copper (Cu) and have a stacked structure of a copper film (Cu film) and a copper-manganese alloy film (CuMn alloy film). More specifically, the source electrode 7S is a stacked film of a Cu film 71S and a CuMn alloy film 72S on the Cu film 71S. Similarly, the drain electrode 7D is a stacked film of a Cu film 71D and a CuMn alloy film 72D on the Cu film 71D.

The structure of the source lines 150 is also similar to those of the source electrode 7S and the drain electrode 7D. That is, the source lines 150 are Cu lines including a stacked film of a Cu film 151 and a CuMn alloy film (cap film) 152 on the Cu film 151.

Using Cu, which is a low-resistance material, for the source electrode 7S, the drain electrode 7D, and the source lines 150 in this way can reduce the resistances of the source electrode 7S and the drain electrode 7D and can make the source lines 150, which are formed in the same layer as the source electrode 7S and the drain electrode 7D, low-resistance lines. Note that the film thickness of the Cu films 71S, 71D, and 151 may be set to greater than the film thickness of the CuMn alloy films 72S, 72D, and 152.

In addition, the Cu films of the source electrode 7S, the drain electrode 7D, and the source lines 150 are coated with the cap films, which reduces the occurrence of oxidation of Cu atoms in the Cu films and deterioration of the Cu films. This suppresses an increase in the resistances of the source electrode 7S, the drain electrode 7D, and the source lines 150 due to oxidation of Cu. In the present embodiment, the CuMn alloy films 72S, 72D, and 152 are used as the uppermost layers (cap films) of the source electrode 7S, the drain electrode 7D, and the source lines 150. In the specification, the CuMn alloy films refer to alloy films of copper and manganese.

The insulating layer 8 is a passivation layer and formed on the insulating layer 6 to cover the source electrode 7S, the drain electrode 7D, and the source lines 150. The insulating layer 8 is a stacked film of a plurality of silicon oxide films (SiO₂), and in the present embodiment, has a two-layer structure of a first silicon oxide film 81 as a lower layer and a second silicon oxide film 82 as an upper layer. A total film thickness of the first silicon oxide film 81 and the second silicon oxide film 82 may be set to greater than or equal to 460 nm.

While the insulating layer 8 in the present embodiment has a stacked structure of only silicon oxide films, the insulating layer 8 may have a stacked structure of other oxide films, such as a stacked structure of a silicon oxide film and an aluminum oxide film (Al₂O₃).

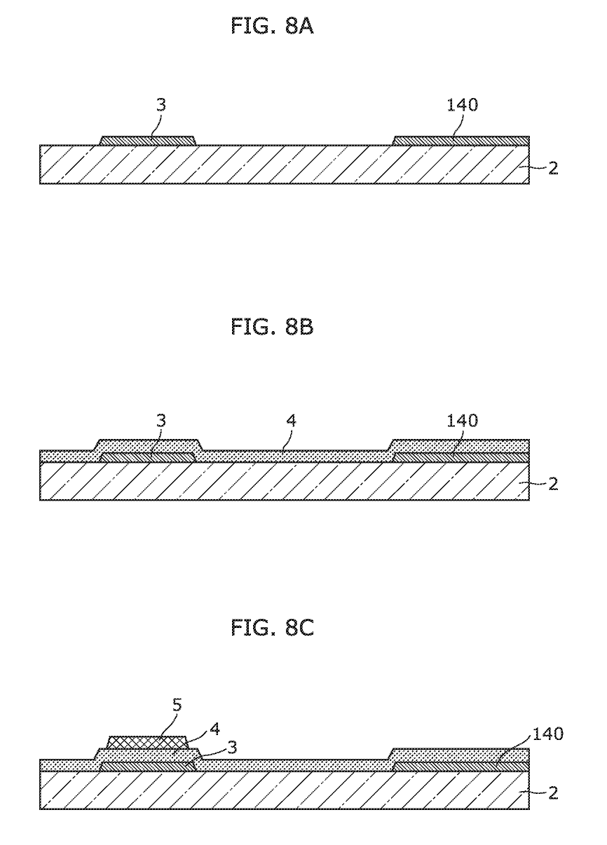

For example, the insulating layer 8 may have a three-layer structure of a first silicon oxide film 81 as a lower layer, an aluminum oxide film 83 as an intermediate layer, and a second silicon oxide film 82 as an upper layer as illustrated in FIG. 6. Including the aluminum oxide film in the insulating layer 8 in this way can suppress the entry of, for example, hydrogen and moisture into the oxide semiconductor layer 5. That is, the electrical characteristics of the oxide semiconductor layer 5 are damaged and degraded by hydrogen or oxygen, but the presence of the aluminum oxide film above the oxide semiconductor layer 5 prevents the entry of hydrogen or moisture generated in the upper layer, thus suppressing the diffusion of hydrogen or moisture in the oxide semiconductor layer 5. Accordingly, the oxide semiconductor layer 5 with stable electrical characteristics is obtained.

While the source electrode 7S, the drain electrode 7D, and the source lines 150 in the present embodiment have a two-layer structure of the Cu film and the CuMn alloy film, the present disclosure is not limited to this example. For example, they may have a three-layer structure of a molybdenum (Mo) or CuMn film, a Cu film, and a CuMn alloy film in order from below.

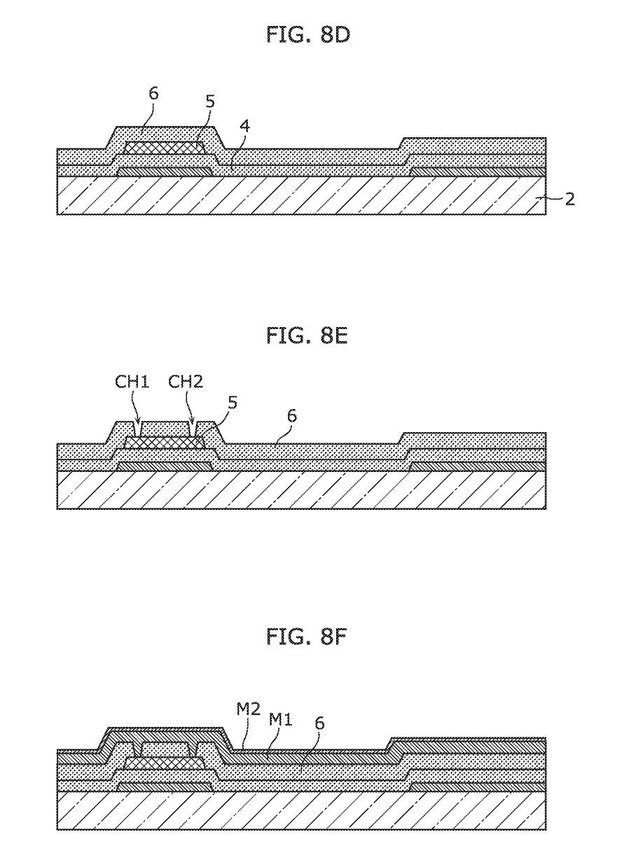

More specifically, the source electrode 7S may be a stacked film of a primary film that is either a molybdenum (Mo) or CuMn film, the Cu film 71S, and the CuMn alloy film 72S as illustrated in FIG. 7. Similarly, the drain electrode 7D may be a stacked film of a primary film 73D that is either an Mo or CuMn film, the Cu film 71D, and the CuMn alloy film 72D, and the source lines 150 may be a stacked film of a primary film 153 that is either an Mo or CuMn film, the Cu film 151, and the CuMn alloy film 152. Using a CuMn or Mo films as the lowermost layers of the source electrode 7S, the drain electrode 7D, and the source lines 150 in this way can suppress diffusion of Cu atoms of the Cu film in the lower layer (e.g., oxide semiconductor layer 5) and can improve adhesion to the oxide semiconductor layer 5.

Method of Manufacturing Thin-Film Transistor Substrate

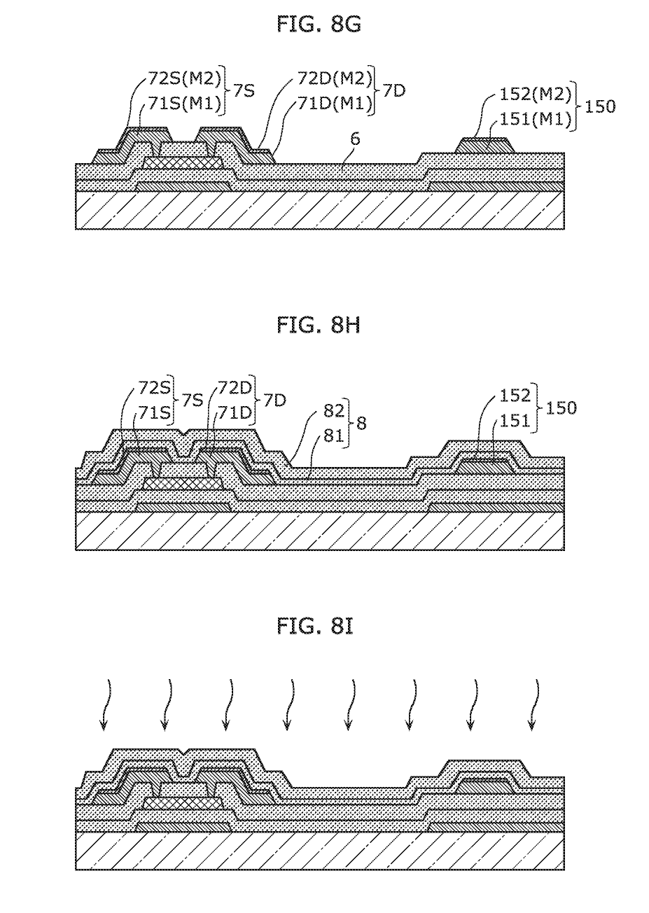

Next, a method of manufacturing the TFT substrate 1 according to the embodiment will be described with reference to FIGS. 8A to 8I. FIGS. 8A to 8I are cross-sectional views illustrating steps in the method of manufacturing a thin-film transistor substrate according to the embodiment.

First, as illustrated in FIG. 8A, the substrate 2 is prepared, and the gate electrode 3 and the gate lines 140 of predetermined shapes are formed above the substrate 2. For example, a metal film is deposited by sputtering on the substrate 2, which is a G8 glass substrate, and processed by photolithography and wet etching to form the gate electrode 3 and the gate lines 140 of predetermined shapes.

Next, as illustrated in FIG. 8B, the gate insulating film 4 (first insulating layer) is formed above the substrate 2. For example, the gate insulating film 4 made of a silicon oxide film is deposited by, for example, plasma CVD on the entire surface of the substrate 2 to cover the gate electrode 3 and the gate lines 140.

Then, as illustrated in FIG. 8C, the oxide semiconductor layer 5 of a predetermined shape is formed above the substrate 2. In the present embodiment, the oxide semiconductor layer 5 is formed on the gate insulating film 4.

For example, a transparent amorphous oxide semiconductor of InGaZnOₓ is deposited by, for example, sputtering on the gate insulating film 4 and processed by photolithography and etching to form the oxide semiconductor layer 5 of a predetermined shape above the gate electrode 3.

Then, as illustrated in FIG. 8D, the insulating layer 6 (second insulating layer) is formed on the gate insulating film 4 to cover the oxide semiconductor layer 5. For example, the insulating layer 6 made of a silicon oxide film is deposited by plasma CVD on the entire surface of the substrate 2.

Then, as illustrated in FIG. 8E, part of the insulating layer 6 is removed to form contact holes CH1 and CH2 for establishing contact between the oxide semiconductor layer 5 and the source and drain electrodes 7S and 7D. For example, the contact holes CH1 and CH2 are formed by photolithography and etching in the insulating layer 6 to expose part of the oxide semiconductor layer 5.

Then, as illustrated in FIG. 8F, a metal stacked film of a Cu film and a CuMn alloy film is deposited. More specifically, a first metal film M1 made of a Cu film is deposited by sputtering on the insulating layer 6 to fill in the contact holes CH1 and CH2 of the insulating layer 6, and then a second metal film M2 made of a CuMn alloy film is deposited by sputtering on the first metal film M1.

Then, as illustrated in FIG. 8G, the metal stacked film of the first metal film M1 (Cu film) and the second metal film M2 (CuMn alloy film) is processed into a predetermined shape by photolithography and etching. In the present embodiment, the metal stacked film of the first metal film M1 and the second metal film M2 is patterned by wet etching using a hydrogen peroxide solution. The etchant may be a mixed aqueous solution of hydrogen peroxide and organic acid.

This patterning forms the source electrode 7S having a stacked structure of the Cu film 71S and the CuMn alloy film 72S and the drain electrode 7D having a stacked structure of the Cu film 71D and the CuMn alloy film 72D as illustrated in FIG. 8G. In this way, the source electrode 7S and the drain electrode 7D are formed on the insulating layer 6 to be connected to the oxide semiconductor layer 5.

This patterning also forms the source lines 150, which are copper lines having a stacked structure of the Cu film 151 and the CuMn alloy film 152 as illustrated in FIG. 8G. Although not shown, the power lines 160 are also formed at the same time.

Then, as illustrated in FIG. 8H, the insulating layer 8 (third insulating layer) is deposited on the source lines 150, which are Cu lines. More specifically, the insulating layer 8 is deposited on the insulating layer 6 to cover the source electrode 7S, the drain electrode 7D, and the source lines 150.

This step includes a step of depositing the first silicon oxide film 81 (lower layer) at a film deposition temperature of 290° C. or lower and a step of depositing the second silicon oxide film 82 (upper layer) above the first silicon oxide film 81 at a film deposition temperature of 290° C. or lower.

For example, the substrate temperature (film deposition temperature) is set to 290° C. or lower, and the first silicon oxide film 81 is deposited by plasma CVD to cover the source electrode 7S, the drain electrode 7D, and the source lines 150. In the step of depositing the first silicon oxide film 81, as a result of depositing the first silicon oxide film 81, part of the Cu films 71S and 71D are in contact with at least part of the first silicon oxide film 81 without being covered with the CuMn alloy films 72S and 72D. Following the deposition of the first silicon oxide film 81, the substrate temperature is set to 290° C. or lower, and the second silicon oxide film 82 is deposited by plasma CVD on the first silicon oxide film 81.

At this time, the first silicon oxide film 81 and the second silicon oxide film 82 are deposited such that a total film thickness of the first silicon oxide film 81 and the second silicon oxide film 82 becomes greater than or equal to 460 nm.

Note that the film deposition temperature of the first silicon oxide film 81 is more preferably 230° C. or lower. The film deposition temperature of the second silicon oxide film 82 is more preferably higher than 230° C.

When the aluminum oxide film 83 is deposited as an intermediate layer between the first silicon oxide film 81 and the second silicon oxide film 82 as illustrated in FIG. 6, the procedure may be such that the aluminum oxide film 83 is deposited by, for example, sputtering after the deposition of the first silicon oxide film 81, and then the second silicon oxide film 82 is deposited thereon.

Next, as illustrated in FIG. 8I, heat treatment (annealing) is performed at a temperature over 290° C. This heat treatment step is performed to stabilize the characteristics of the oxide semiconductor layer 5, and performed at, for example, a set temperature of 300° C. This heat treatment can correct oxygen deficiency in the oxide semiconductor layer 5 and thereby stabilize the characteristics of the oxide semiconductor layer 5.

Circumstances Leading to Present Disclosure and Conditions for Depositing Insulating Layer

The conditions for depositing the insulating layer 8, which is a feature of the present disclosure, will now be described in detail, along with the circumstances leading to the present disclosure.

Large display devices and organic EL display devices use low-resistance metal lines for lines (source lines, gate lines, and power lines) of TFT substrates in order to implement high-speed driving. The source lines and the power lines are made of the same material as and formed in the same layer as the source and drain electrodes of TFTs. It is thus necessary to consider performance not only in terms of the TFTs but also in terms of the lines in selecting the material for the source and drain electrodes and the lines formed in the same layer as the source and drain electrodes. In view of this, consideration is given to using copper (Cu) with low resistance as the material for the source electrode, the drain electrode, and the source lines.

In the TFTs using an oxide semiconductor, a silicon oxide film is used as an interlayer insulation film (insulating layer). For example, an interlayer insulation film made of a silicon oxide film is formed to cover the source electrode, the drain electrode, and the source lines.

It is, however, difficult in the TFT substrate to establish compatibility between the use of a silicon oxide film as the interlayer insulation film and the use of Cu as the material for the source electrode, the drain electrode, and the source lines. This is because the copper surface is easily oxidized and has low adhesion to the silicon oxide film.

Therefore, consideration is given to a technique for forming a cap film (protective layer) such as a CuMn alloy film between the silicon oxide film and the Cu films of the source electrode, the drain electrode, and the source lines. That is, it is conceivable to provide the source electrode, the drain electrode, and the source lines with a stacked structure of a Cu film and a cap film. Forming the cap film on the surface of the Cu film prevents the Cu film from coming in direct contact with the silicon oxide film, thus stabilizing processing.

However, it turned out that a phenomenon of abnormal growth of Cu from the Cu film occurs in the stacked film of the Cu film and the cap film.

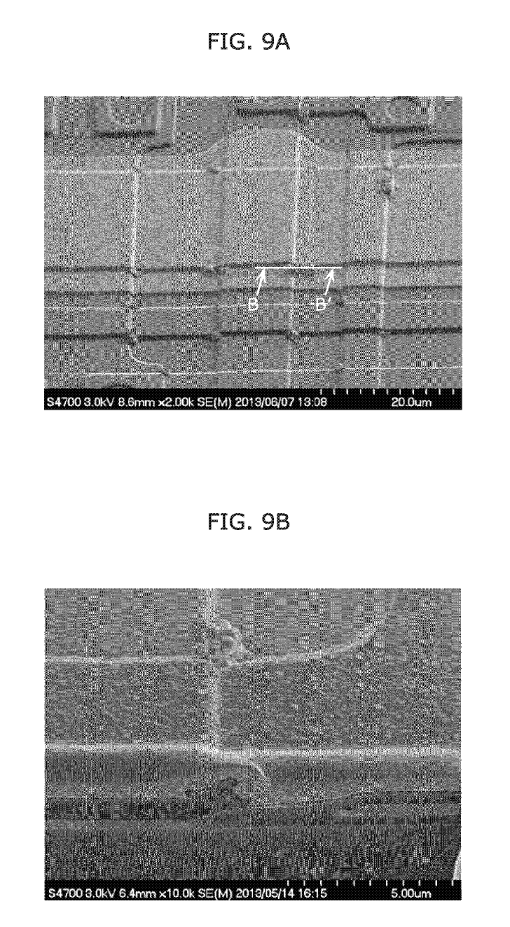

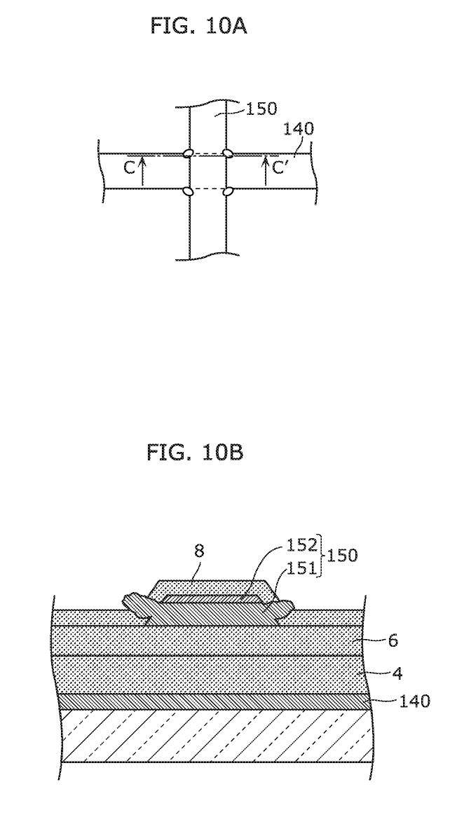

For example, such abnormal Cu growth from the Cu film intensively occurs at the edges of the source lines at the intersections thereof with the gate lines as illustrated in FIGS. 9A, 9B, 10A, and 10B.

FIGS. 9A and 9B illustrate SEM images showing abnormal growth of Cu from the Cu film 151 of a source line 150 at the intersection of a gate line 140 and the source line 150. FIG. 9A illustrates an in-plane SEM image, and FIG. 9B illustrates a cross-sectional SEM image taken along line B-B′ in FIG. 9A.

FIGS. 10A and 10B schematically illustrate abnormal growth of Cu from the Cu film 151 of a source line 150 at the intersection of a gate line 140 and the source line 150. FIG. 10A is a plan view, and FIG. 10B is a cross-sectional view taken along line C-C′ in FIG. 10A.

After careful consideration of the cause of this abnormal Cu growth, the inventors of the present disclosure have found that the abnormal Cu growth is caused by the following factors.

Specifically, when the silicon oxide film is deposited after patterning of the stacked film of the Cu film and the cap film, the upper surface of the Cu film is covered with the cap film and is thus not in contact with the silicon oxide film. However, at the end surface (side surface) of the stacked film, the Cu film is exposed by the patterning of the stacked film and accordingly the Cu film and the silicon oxide film are in direct contact with each other. Thus, it can be thought that the abnormal Cu growth from the Cu film occurs due to, for example, the effect of heat generated in subsequent steps. One example of the subsequent steps is heat treatment (e.g., 300° C. annealing) performed to stabilize the characteristics of the oxide semiconductor. The abnormal Cu growth from the Cu film causes a problem that deficiencies in quality are caused due to short circuit failure, making it difficult to produce a TFT substrate with desired performance.

In this way, the inventors of the present disclosure found out that the cause of the abnormal Cu growth from the Cu film depends on the conditions for film deposition of the insulating layer 8 above the Cu film and the conditions for annealing performed after the film deposition of the insulating layer 8.

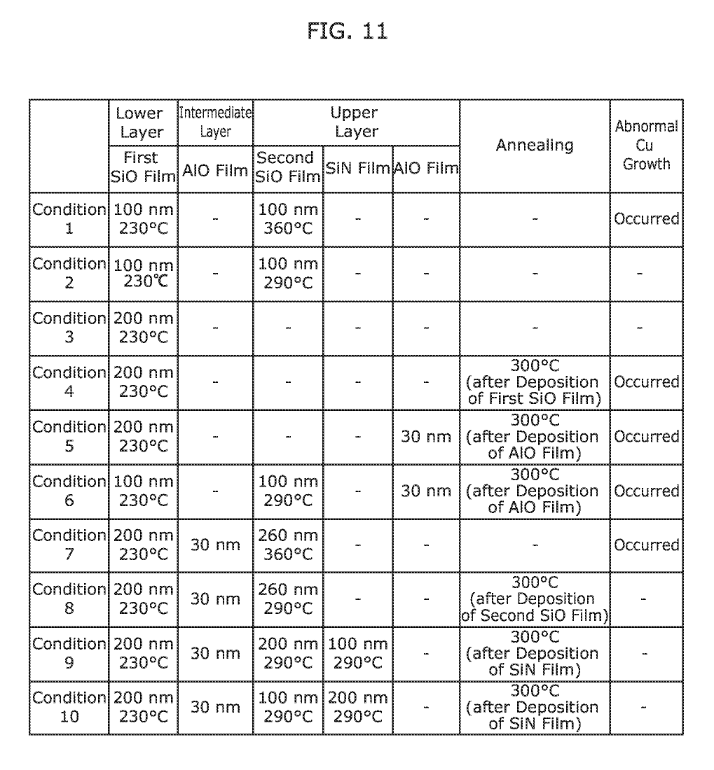

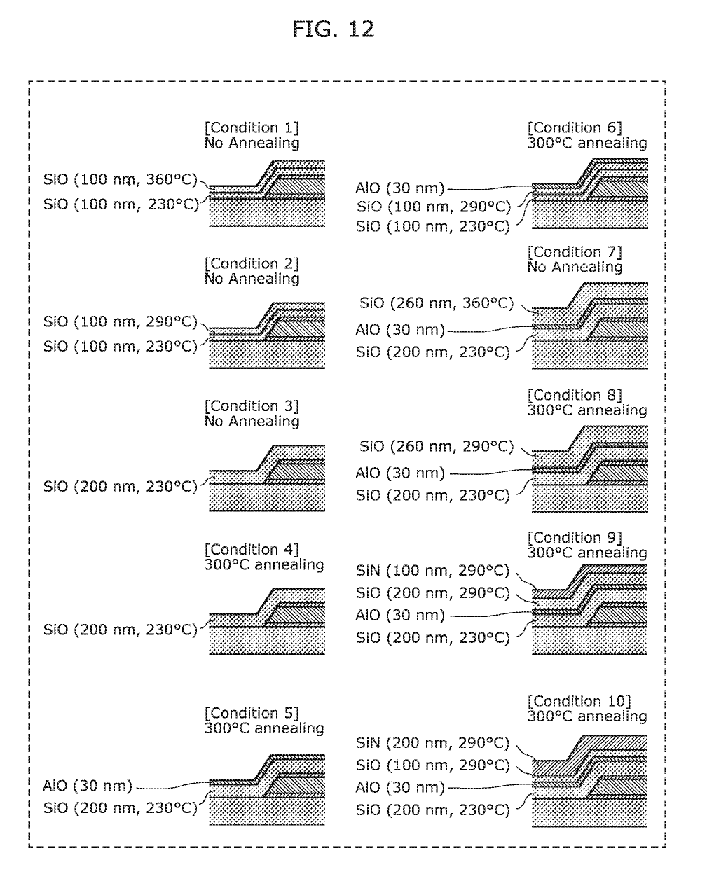

In view of this, the inventors of the present disclosure conducted experiments under ten different conditions, i.e., Conditions 1 to 10 illustrated in FIG. 11, to examine whether abnormal CU growth occurs from the Cu film 151 of the source lines 150 covered with the insulating layer 8. In FIG. 11, the conditions for the insulating layer 8 (lower layer, intermediate layer, and upper layer) are film thickness and film deposition temperature. FIG. 12 schematically illustrates the film structure of the source line 150 and the insulating layer 8 under each condition in FIG. 11.

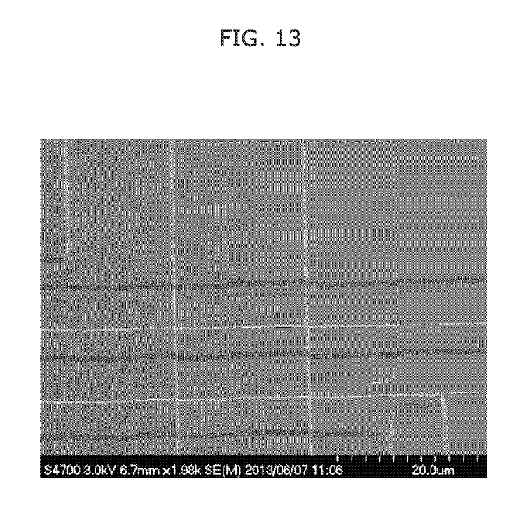

The results of the experiments have shown that abnormal Cu growth occurred under Conditions 1 and 4 to 7, whereas abnormal Cu growth did not occur under Conditions 2, 3, and 8 to 10. FIG. 13 illustrates an in-plane SEM image at the intersection of a gate line 140 and a source line 150 under conditions in which no abnormal Cu growth occurred.

A comparison of FIG. 13 and FIG. 10A, which was described above, shows that no abnormal Cu growth occurred at the edges of the source line at the intersection thereof with the gate line in FIG. 13.

Through the analysis of this experimental results, the following is found about the occurrence of abnormal Cu growth.

First, it can be seen that the processing temperature after the deposition of the first silicon oxide film (first SiO film), which is the lower layer, is preferably set to low. For example, the film deposition temperature of the second silicon oxide film (second SiO film), which is the upper layer, and the annealing temperature are preferably set to low.

It can also be seen that the total film thickness of the insulating layer is preferably set to greater than or equal to a fixed value. It is clear that when the total film thickness of the insulating layer is greater than or equal to a fixed value, abnormal Cu growth does not occur even if the film deposition temperature of the second silicon oxide film (second SiO film) is high or annealing is performed.

It can also been seen that the insertion of the aluminum oxide film (AlO film) as an intermediate layer has little effect on the occurrence of abnormal Cu growth. In addition, the deposition of the silicon nitride film also has little effect on the occurrence of abnormal Cu growth.

In summary, it has been found that abnormal Cu growth occurs or does not occur depending on the film deposition temperatures of the first silicon oxide film (first SiO film) and the second silicon oxide film (second SiO film) and the total film thickness of the first silicon oxide film and the second silicon oxide film. It has also been found that if the total film thickness of the insulating layer 8 is less than a predetermined film thickness, abnormal Cu growth occurs when the film deposition temperature of the upper layer of the insulating layer 8 is high or due to subsequent execution of 300° C. annealing.

The experiments under Conditions 2 and 3 show that even if the total film thickness of the insulating layer 8 is small, abnormal Cu growth does not occur as long as 300° C. annealing is not performed. However, annealing is preferably performed after the film deposition of the insulating layer 8 in order to stabilize the characteristics of the oxide semiconductor layer 5.

The present disclosure is based on the above findings, and the inventors of the present disclosure found out that even if heat treatment is performed after film deposition of the insulating layer 8 on the Cu lines (e.g., source lines 150), abnormal Cu growth from the Cu lines can be suppressed by depositing the insulating layer 8 under predetermined film deposition conditions.

That is, the inventors have found out that abnormal Cu growth from the Cu lines can be suppressed if, in the process of depositing the insulating layer 8, the film deposition temperatures of the first silicon oxide film 81 and the second silicon oxide film 82 are set to a fixed temperature or lower, and the total film thickness of the first silicon oxide film 81 and the second silicon oxide film 82 is set to a fixed film thickness or more.

In this case, it is thought that the maximum film deposition temperature of the first silicon oxide film 81 needs to be approximately 290° C. This is because although abnormal Cu growth occurred under Condition 7 in FIG. 11 using a film deposition temperature of 360° C., abnormal Cu growth was suppressed even after annealing under Condition 8 using a film deposition temperature of 290° C.

Similarly, it is thought that the maximum film deposition temperature of the second silicon oxide film 82 needs to be approximately 290° C.

In this way, from the viewpoint of suppressing abnormal Cu growth, the maximum film deposition temperatures of the first silicon oxide film 81 and the second silicon oxide film 82 are preferably 290° C. or lower.

In the above-described method of manufacturing a thin-film transistor according to the present embodiment, the insulating layer 8 is formed on the Cu lines in such a way that the first silicon oxide film 81 is deposited at a film deposition temperature of 290° C. or lower, then the second silicon oxide film 82 is deposited above the first silicon oxide film 81 at a film deposition temperature of 290° C. or lower, and the total film thickness of the first silicon oxide film 81 and the second silicon oxide film 82 is greater than or equal to 460 nm. With this method, it is possible to manufacture the TFT substrate 1 provided with thin-film transistors in which abnormal Cu growth does not occur from the Cu lines and that have desired pressure resistance characteristics.

In the present embodiment, the film deposition temperature of the first silicon oxide film 81 formed immediately on the CuMn alloy film (cap film) is preferably 230° C. or lower.

The results of the experiments conducted by the inventors of the present disclosure proved that the surface of the CuMn alloy film deteriorates if the film deposition temperature of the first silicon oxide film 81 formed immediately on the CuMn alloy film is over 230° C. More specifically, the surface of the CuMn alloy film does not deteriorate when the film deposition temperature of the first silicon oxide film 81 is 230° C., but deteriorates when the film deposition temperature of the first silicon oxide film 81 is 245° C.

The deterioration of the surface of the CuMn alloy film lessens the effect of the CuMn film. It is thus desirable for the first silicon oxide film 81 to be deposited at a film deposition temperature of 230° C. or lower.

In this way, when consideration is given to the viewpoint of suppressing deterioration of the surface of the CuMn film in addition to the viewpoint of suppressing abnormal Cu growth, the maximum film deposition temperature of the first silicon oxide film 81 is preferably 230° C. or lower.

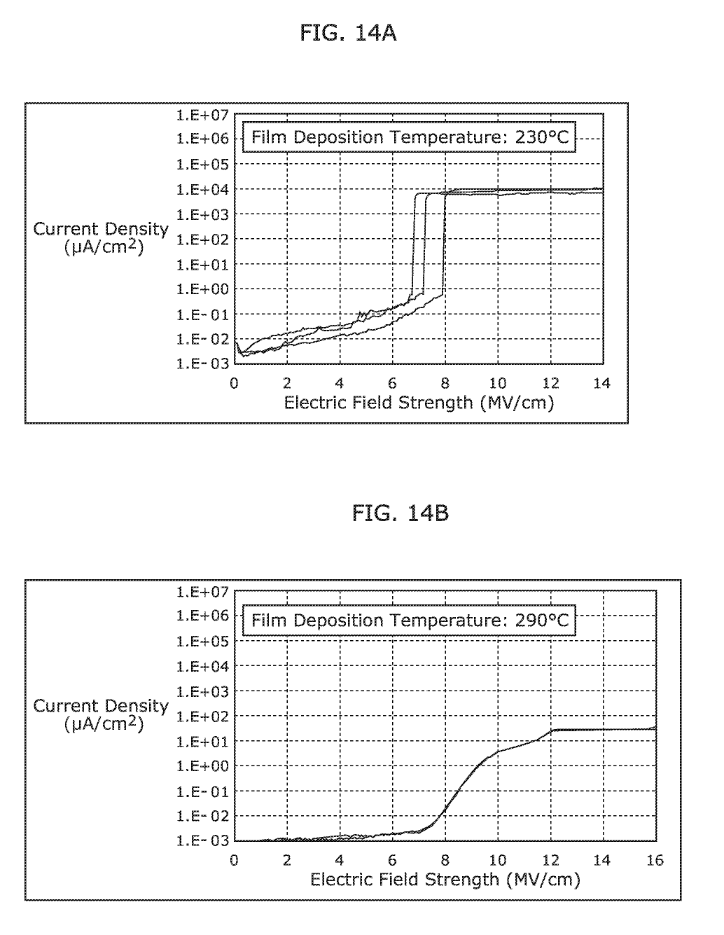

Moreover, the film deposition temperature of the second silicon oxide film 82 is preferably such a temperature at which dielectric strength can be secured. This point will now be described with reference to FIGS. 14A and 14B. FIG. 14A illustrates a relationship between electric field strength and current density in a metal-oxide-metal structure obtained by depositing the second silicon oxide film 82 at a film deposition temperature of 230° C. FIG. 14B illustrates a relationship between electric field strength and current density in a metal-oxide-metal structure obtained by depositing the second silicon oxide film 82 at a film deposition temperature of 290° C. FIG. 14A illustrates experimental results for three samples.

As illustrated in FIG. 14A, dielectric strength becomes insufficient when the second silicon oxide film 82 is deposited at a film deposition temperature of 230° C. In this case, desired thin-film transistors cannot be obtained.

On the other hand, FIG. 14B shows that dielectric strength can be secured when the second silicon oxide film 82 is deposited at a film deposition temperature of 290° C. In this case, desired thin-film transistors can be obtained.

In this way, dielectric strength can be secured if the film deposition temperature of the second silicon oxide film 82 is at least 290° C. From the viewpoint of securing dielectric strength, it was also found that the minimum film deposition temperature of the second silicon oxide film 82 is at least higher than 230° C.

In this way, when consideration is given to the viewpoint of securing dielectric strength in addition to the viewpoint of suppressing abnormal Cu growth and the viewpoint of suppressing deterioration of the surface of the CuMn film, it is desirable for the first silicon oxide film 81 to be deposited at a film deposition temperature of 230° C. or lower and for the second silicon oxide film 82 to be deposited at a film deposition temperature that is higher than 230° C. and is lower than or equal to 290° C.

Variations

While the above has been a description of an embodiment of the thin-film transistor substrate, a method of manufacturing a thin-film transistor substrate, and an organic EL display device, the present disclosure is not limited to the embodiment described above.

For example, while the thin-film transistors in the above-described embodiment are bottom-gate type transistors, they may be top-gate type transistors.

While the thin-film transistors in the above-described embodiment are channel etching stopper type (channel protective) transistors, they may be channel etching type transistors. That is, the insulating layer 6 may not be formed in the above-described embodiment.

While the above embodiment describes the organic EL display device as an example of the display device using a thin-film transistor substrate, the thin-film transistor substrate in the above-described embodiment is also applicable to other display devices using an active matrix substrate, such as liquid crystal display devices.

The display devices (display panels) such as the above-described organic EL display device are usable as flat panel displays and are applicable to various types of electronic devices such as TV sets, personal computers, or mobile phones that include a display panel. In particular, they are suitable for large-screen, high definition display devices.

The present disclosure also includes other embodiments such as those obtained by making various modifications conceived by those skilled in the art to the above-described embodiment and variations, and those achieved by arbitrarily combining the constituent elements and functions of the above-described embodiment and variations without departing from the scope of the present disclosure.

### INDUSTRIAL APPLICABILITY

The technique disclosed herein is widely usable for, for example, thin-film transistor substrates using oxide semiconductors, methods of manufacturing such thin-film transistor substrates, and display devices using thin-film transistor substrates such as organic EL display devices.

1. A method of manufacturing a thin-film transistor substrate that includes a thin-film transistor having an oxide semiconductor layer, the method comprising:
forming a copper line above a substrate, the copper line including a stacked film that includes a copper film and a cap film on the copper film;
depositing an insulating layer on the copper line; and
performing heat treatment at a temperature over 290° C. after the deposition of the insulating layer,
wherein the depositing of the insulating layer includes:
depositing a first silicon oxide film at a film deposition temperature of 290° C. or lower; and
depositing a second silicon oxide film above the first silicon oxide film at a film deposition temperature of 290° C. or lower, and
a total film thickness of the first silicon oxide film and the second silicon oxide film is greater than or equal to 460 nm.

2. The method according to claim 1,
wherein the film deposition temperature of the first silicon oxide film is 230° C. or lower, and
the film deposition temperature of the second silicon oxide film is higher than 230° C.

3. The method according to claim 1,
wherein in the depositing of the first silicon oxide film,
as a result of depositing the first silicon oxide film, part of the copper film is in contact with at least part of the first silicon oxide film without being covered with the cap film.

4. The method according to claim 1,
wherein the cap layer is a CuMn alloy film.
